(19) United States
(12) Patent Application Publication
(10) Pub. No.: US 2015/0309139 A1
(43) Pub. Date: Oct. 29, 2015

(54) METHOD AND MAGNETIC RESONANCE APPARATUS FOR SLICE-SELECTIVE MAGNETIC RESONANCE IMAGING

(71) Applicant: Siemens Aktiengesellschaft, Muenchen (DE)

(72) Inventors: Theresa Bachschmidt, Erlangen (DE); Dominik Paul, Bubenreuth (DE)

(73) Assignee: SIEMENS AKTIENGESELLSCHAFT, Muenchen (DE)

(21) Appl. No.: 14/699,366

(22) Filed: Apr. 29, 2015

(30) Foreign Application Priority Data
Apr. 29, 2014 (DE) 102014208063.0

(51) Int. Cl. G01R 33/483; G01R 33/341; G01R 33/28; G01R 33/385; G01R 33/565; G01R 33/54

(52) U.S. Cl. CPC G01R 33/4835; G01R 33/56563; G01R 33/56536; G01R 33/543; G01R 33/288; G01R 33/385; G01R 33/341

(57) ABSTRACT

In a method and magnetic resonance apparatus for slice-selective magnetic resonance imaging, read partitions in a cyclical sequence of slices are read out. At least two slices have a different number of read partitions. The same predefined number of read partitions for the slices is read out in all cycles of the sequence. SEMAC techniques are used.

### BACKGROUND OF THE INVENTION

1. Field of the Invention

The invention concerns techniques for slice-selective magnetic resonance imaging of an examination object and a magnetic resonance apparatus implementing such techniques. In particular the invention concerns those techniques that, enable a reduced measuring time and/or radio-frequency exposure to radiation and/or energy deposition, for example, based on a Slice Encoding for Metal Artifact Correction measuring sequence.

2. Description of the Prior Art

In magnetic resonance (MR) imaging, nuclear spins of a subject are oriented or polarized by applying a basic magnetic field, and are then deflected from the rest position or purposefully manipulated, for example refocused, by radiating one or more radio-frequency (RF) pulse(s). It may occur that the polarizing magnetic field exhibits localized inhomogeneities, i.e. variations as a function of spatial location within the field. This may be the case, for example, due to structurally-caused inhomogeneities in the basic magnetic field and/or due to the presence of changes in susceptibility as a function of location. Such changes in susceptibility can occur, for example, due to metal objects in the examination area, for instance prostheses or surgical elements.

These inhomogeneities can cause image artifacts in MR images, because the localized resonance frequency of the nuclear spins is shifted by the inhomogeneities, and disturbances consequently occur in the MR data. A specific point in the spatial domain may therefore be mapped at a different point in the MR image. Corresponding distortions can occur as early as in the excitation profiles excited by a slice-selective RF pulse.

To suppress metal artifacts in spin echo (SE)-based measuring sequences, the Slice Encoding for Metal Artifact Correction (SEMAC) technique may be used, see “SEMAC: Slice Encoding for Metal Artifact Correction in MRI”, W. Lu et al. Magn. Reson. in Med. 62 (2009) 66-76. An additional phase encoding in the slice-selective direction kz is typically carried out in conjunction with a conventional two-dimensional (2D) measuring sequence or slice-selective scanning of an examination object; this fixes what are known as read partitions.

Two effects can occur in conjunction with SEMAC techniques of this kind. First, the overall time frame (measuring time) required for acquiring MR data typically increases inherently linearly with the number of additional read partitions in the slice-selection direction kz. This can limit the flexibility in the imaging and cause movement artifacts or the like. At the same time the economic efficiency of the operation of the MR system can be limited. Second, an RF exposure to the patient caused by the MR imaging can increase, and this is usually by the specific absorption rate (SAR). This is typically the case because a large number of refocusing pulses with an RF component are radiated per time. It may consequently be necessary to provide additional dead times to limit the SAR, and consequently extend the measuring time further.

Techniques are known in connection with SAR reduction in which a different number of read partitions are chosen for different slices. It may be advantageous, for example, to read out a larger (or smaller) number of read partitions for those slices for which a strong (or weak) distortion due to magnetic field inhomogeneities is expected. Dead times, i.e. times without switching (activation) of gradients, in which the measurement temporarily pauses, typically result due to this omission of read partitions for certain slices. No MR data are acquired during the dead times. These dead times also increase the measuring time unnecessarily.

### SUMMARY OF THE INVENTION

There is therefore a need for improved techniques for the correction of metal artifacts in MR data. In particular there is a need for those techniques which enable a comparatively short measuring time or a comparatively low SAR. At the same time the techniques should enable good quality MR data. There is a need in particular for such techniques that enable a balance between reduced SAR and reduced measuring time.

According to one aspect, the invention encompasses a method for slice-selective MR imaging of multiple slices of an examination object. The MR imaging takes into account, for each of the multiple slices, MR data of multiple read partitions of the multiple slices for the reduction of image artifacts due to magnetic field inhomogeneities. The slices are adjacent to each other in a first direction and extend perpendicularly to the first direction. The multiple read partitions of each slice are adjacent to each other in the first direction. At least two slices have a different number of read partitions. The method includes reading out the read partitions in a cyclical sequence of slices, wherein successively read partitions belong to different slices. A minimum repetition time between the sequential reading out of read partitions of the same slice is thereby ensured. The same predefined number of read partitions for the slices is read out in all cycles of the sequence. The sequence includes at least two sub-sequences that are different from each other and that differ at least in relation to one slice respectively. The method also includes, for each slice, determining an MR image based on the MR data of the read partitions of that respective slice and based on MR data of the read partitions of further slices.

The MR imaging thus can be based on an interleaved SEMAC MR measuring sequence. Here read partitions are alternately read out for different slices. Because different slices have a different number of read partitions, asymmetric SEMAC techniques are often also mentioned. The read partitions are frequently also called SEMAC steps.

It may be possible, for example, to choose a variable number of read partitions for the various slices, for example as a function of the position of the respective slice. In this way it may be possible to minimize a total number of read partitions and thereby reduce SAR exposure for an examination person—particularly in comparison to the case in which the same number of read partitions is read out for all slices. It may also be possible to reduce the measuring time because a smaller amount of MR data needs to be acquired.

One cycle of the sequence can, for example, denote the longest repetition time that occurs during reading out between the successive reading out of read partitions of the same slice. It would also be possible for a cycle to be determined with respect to the number of slices of the longest sub-sequence. A length of the cycle of the sequence can therefore be equal to the length of the cycle of the sub-sequence with the largest number of read-out read partitions per cycle.

It can typically be desirable to choose the number of read-out read partitions per cycle to be as high as possible in order to ensure a high repetition time in such a way. A high repetition time typically achieves higher quality MR data since saturation effects of the nuclear spins can be reduced in such a way.

The sequence and the sub-sequences can therefore designate an ordered amount of successively read out slices. Different read partitions can be read out for the slices according to the progress of reading out, i.e. a different read partition is read out for one and the same slice according to cycle. The sequence or sub-sequences can each be run through at least twice, i.e. so as to be at least two cycles. The sequence and/or the sub-sequence can include a minimum number of slices, for example at least three slices each, preferably at least five slices, particularly preferably at least 24 slices.

Since all cycles of the sequence have the same predefined number of read partitions for the slices, particularly efficient reading out can be achieved with respect to time. Dead times can be avoided, as occur with known techniques wherein a different number of read partitions can be read out for different cycles of the sequence, from which dead times result. The dead times typically lengthen the measuring time.

Using the sub-sequences makes it possible, even with a different number of read partitions per slice, to ensure a certain sorting in relation to the successively read out slices. An optimally high effective repetition time, while simultaneously avoiding dead times, can be achieved in this way. The effective repetition time can describe for example a mean of all repetition times that occur during the measuring time.

It is possible, for example, for the predefined number of slices per cycle of the sequence to be smaller than the total number of slices. In other words, it is possible that in a respective cycle of the sequence, read partitions are not read out for all slices. The repetition time between the successive reading out of read partitions of the same slice can then decrease—compared to a case where read partitions for all slices are always read out in each cycle or corresponding dead times are provided. The measuring time can be reduced at the same time, however, due to the avoidance of dead times. Overall, an optimized image quality of the MR images can be obtained in such a way and with a suitable balancing of the effects due to reduced repetition time and due to reduced measuring time. The predefined number for example can be determined, for example, by a user of the MR system, as a function of such a factor.

Accordingly it is also be possible for a total number of cycles of the sequence to be greater than a maximum number of read partitions per slice. In other words, a number of cycles can be comparatively large while a length of the various cycles is at the same time chosen to be comparatively short. It may therefore be possible for read partitions for different slices to be read out in different cycles of the sequence within the context of at least two sub-sequences. It would therefore be possible for example—compared to known techniques—for those read partitions of the various slices, which are located in the respective k-space center, to be read out in different cycles of the sequence.

The at least two sub-sequences can be successively read out or read out in an interleaved manner. Successive reading out can be, for example, first completing reading out of the read partitions of a first sub-sequence before reading out of read partitions of a second sub-sequence is begun. Accordingly, reading out in an interleaved manner can mean: alternately reading out a first sub-sequence and a second sub-sequence. The two sub-sequences can at least partly overlap time-wise in the latter case.

Increased flexibility during reading out of the read partitions for the various slices can be achieved in particular by the interleaved reading out of the at least two sub-sequences. Different slices can be allocated to different sub-sequences. This can particularly efficiently allow dead times to be avoided and a measuring time to be reduced overall. At the same time, however, the repetition time between the successive reading out of read partitions of the same slice can be reduced; overall a balancing of the two criteria of measurement duration and effective repetition time can be desirable.

In general, different sub-sequences can have a different number of read-out read partitions of slices; the sub-sequences can therefore comprise different numbers of slices. It is possible for at least the cycle of a first sub-sequence to have the same number of read-out read partitions of slices as the cycle of the sequence. It is also possible for at least the cycle of a second sub-sequence to have a lower number of read-out read partitions of slices than the cycle of the sequence. In other words, specific sub-sequences can have a lower number of read-out read partitions of slices than other sub-sequences. It would also be possible, however, for all sub-sequences to have the same number of read-out read partitions for slices. The cycle of the sequence can be defined by the first sub-sequence. The first sub-sequence can be the longest sub-sequence.

If sub-sequences with a comparatively low number of read-out read partitions are also used, then the available measuring time can in particular be flexibly used for different read partitions of different slices. This can be desirable in particular if different slices have a different number of read partitions, because significant dead times can be prevented from occurring in such a way by way of the flexible sorting and distribution of slices among the various sub-sequences. A repetition time of the first sub-sequence can accordingly be longer than a repetition time of the second sub-sequence.

It is possible for the cycles of the at least two sub-sequences to have the same predefined number of read-out read partitions as the cycle of the sequence. This may be possible if different sub-sequences have the same number of read-out read partitions. A particularly long effective repetition time can be ensured in this way.

Read partitions for different slices can be read out in the at least two sub-sequences. It is therefore possible, for example, for a first group of those slices, whose read partitions are read out in a first sub-sequence, to differ from a second group of those slices, whose read partitions are read out in a second sub-sequence. The first and second groups can be mutually disjunct, for example, or can overlap (but not completely). In general at least one slice can be provided in the first group which is not provided in the second group.

Of course, in general more than two sub-sequences may be used. More than 20 or more than 100 sub-sequences can for example be used. There can accordingly be a plurality of partly overlapping slices or disjunct amounts of slices which are allocated to the respective sub-sequences.

The total number of cycles of the sequence can be equal to the total number of read partitions of all slices divided by the maximum number of read partitions per slice. This can cause the effect of a reduced measuring time. A reduced measuring time can be achieved in particular compared with conventional techniques, in which typically a total number of cycles of the sequence are equal to the maximum number of read partitions per slice.

It is also possible for each cycle of the sequence of slices to comprise a predefined dead time without the application of gradients and radio-frequency pulses without predefined duration. In particular the predefined dead time can for example be the same for each cycle. The additional provision of dead times per cycle means that an SAR exposure for an examination person is reduced. It is also possible for the dead time to be different for different cycles of the sequence. For example, the incorporated dead time can increase as the measuring time increases or depend on the measuring time in some other way.

A number of read partitions per slice can be chosen as a function of a distance of the slice from a predefined location. For example, the location can mark a source of the magnetic field inhomogeneities. Alternatively or additionally it is possible for the location to be determined as a function of a measured off-resonance of the respective slice. See for instance German patent application DE 10 2013 205 930.2 and U.S. patent application 61/918,786 in this regard. Using such techniques can mean that a large number of read partitions are not read out unnecessarily per slice. In particular the number of read partitions for each slice can be chosen as a function of the severity of the local distortion in such a way that an optimum between increased SAR exposure and quality of the MR data is ensured.

Reading out of a read partition can include the following steps respectively for each slice: slice-selective excitation of nuclear spins by applying at least one slice selection gradient in the first direction and by time-correlated radiation of at least one excitation pulse; and slice-selective refocusing of excited nuclear spins by sequential application of multiple further slice selection gradients in the first direction and by time-correlated radiation of multiple refocusing pulses. The read-out for each further slice selection gradient with associated refocusing pulse includes applying at least one kz-phase encoding gradient in the first direction for defining a read partition in each case; and applying at least one ky-phase encoding gradient in a second direction for acquiring the MR data, wherein the first direction and the second direction are oriented perpendicularly to each other.

According to a further aspect the invention encompasses an MR apparatus designed for slice-selective MR imaging of multiple slices of an examination object. For each of the multiple slices, the MR imaging takes into account MR data of multiple read partitions of the multiple slices for the reduction of image artifacts due to magnetic field inhomogeneities. The slices are adjacent to each other in a first direction and extend perpendicularly to the first direction. The multiple read partitions of each slice are adjacent to each other in the first direction. The at least two slices have a different number of read partitions. The MR apparatus has an MR scanner that is operated by a control computer to read out the read partitions in a cyclical sequence of slices to obtain the MR data. Successively read-out read partitions belong to different slices, whereby a minimum repetition time between the sequential reading out of read partitions of the same slice is ensured. In all cycles of the sequence the same predefined number of read partitions is read out for the slices. The sequence includes at least two sub-sequences that are different from each other and that each differ at least with respect to one slice. The control computer of the MR apparatus has an arithmetic unit configured to, for each slice, determine an MR image based on the MR data of the read partitions of the respective slice and based on MR data of the read partitions of further slices.

The MR apparatus according to the invention is thus designed to implement the method for slice-selective MR imaging according to the present invention, as described above.

Advantages are achieved with the MR apparatus that are comparable to the advantages achieved by the method for slice-selective MR imaging according to the invention.

The invention also encompasses a method for slice-selective MR imaging multiple slices of an examination object, wherein for each of the multiple slices, the MR imaging takes into account MR data of multiple read partitions of the multiple slices for the reduction of image artifacts due to magnetic field inhomogeneities. The slices are adjacent to each other in a first direction and extend perpendicularly to the first direction. The multiple read partitions of each slice are adjacent to each other in the first direction. At least two slices have a different number of read partitions. The method includes obtaining a data record for a cyclical sequence of slices wherein, in each cycle, at most one read partition per slice is read out. In at least two cycles of the sequence, a different number of read partitions is read out, with dead times occurring during reading out. The method includes re-sorting the sequence, so the dead times are reduced. The method also includes reading out the read partitions for different slices in the re-sorted sequence.

For example, the cyclical sequence of slices can read out read partitions of the different slices strictly sequentially. For example, if there are ten slices, then read partitions can always be read out first—or optionally dead times can occur—for all other slices before a read partition of a specific slice is read out again. A maximum repetition time is always ensured in a strictly sequential case of this kind. The repetition time does not vary over the measuring time, or varies only insignificantly. It is possible in this connection for corresponding read partitions of different slices to be read out in the same cycles of the sequence. For example, all read partitions of the different slices which are located in the k-space center—defined in relation to the slice in each case—can be read out in one specific cycle.

In a simple embodiment the re-sorting causes a random sequence of slices. Read partitions of different slices can be read out randomly distributed over the measuring time.

For example, the re-sorting can occur such that, in the re-sorted sequence, at least two read partitions are read out for the same slice at least in one cycle. It is also possible for the re-sorting to occur such that the same predefined number of read partitions is read out for the slices in all cycles of the re-sorted sequence. By such techniques, it is possible to eliminate corresponding dead times by rearranging read partitions. In other words, the dead times in the original sequence can be eliminated by re-sorting.

In particular, re-sorting can occur such that in the re-sorted sequence a number of read-out read partitions per cycle is lower than a number of read-out read partitions per cycle of the sequence.

Re-sorting can also occur such that in the re-sorted sequence a total number of cycles is greater than a total number of cycles per sequence.

Re-sorting can such that sequences and sub-sequences can be obtained according to the further aspects of the present aspects.

The features illustrated above and features which are described below can be used not only in the corresponding explicitly illustrated combinations but also in further combinations or in isolation without departing from the scope of the present invention.

### BRIEF DESCRIPTION OF THE DRAWINGS

FIG. 1 illustrates magnetic field inhomogeneities as a function of the location in the slice-selection direction.

FIG. 2 illustrates excitation profiles in the presence of magnetic field inhomogeneities, and slice profiles.

FIG. 3 illustrates read partitions for a slice.

FIG. 4 is a schematic view of an MR system.

FIG. 5 illustrates a SEMAC MR measuring sequence in which read partitions for different slices are read out in an interleaved manner.

FIG. 6 illustrates the SEMAC MR measuring sequence for a first read partition of a first slice.

FIG. 7 illustrates the SEMAC MR measuring sequence for a first read partition of a second slice.

FIG. 8 illustrates the SEMAC MR measuring sequence for a second read partition of the first slice.

FIG. 9 illustrates a number of read partitions per slice as a function of the location.

FIG. 10 illustrates a known sequence of slices for reading out read partitions within the context of a SEMAC MR measuring sequence, wherein different cycles of the sequence have a different number of read-out read partitions of the slices.

FIG. 11 illustrates an inventive sequence of slices for reading out read partitions within the context of a SEMAC MR measuring sequence, for which corresponding MR data as in FIG. 10 is obtained, wherein all cycles of the sequence have the same predefined number of read-out read partitions.

FIG. 12 illustrates a known sequence of slices for reading out read partitions within the context of a SEMAC MR measuring sequence, wherein different cycles of the sequence have a different number of read-out read partitions of the slices.

FIG. 13 illustrates an inventive sequence of slices for reading out read partitions within the context of a SEMAC MR measuring sequence, for which corresponding MR data as in FIG. 12 is obtained, wherein all cycles of the sequence have the same predefined number of read-out read partitions.

FIG. 14 illustrates a known sequence of slices for reading out read partitions within the context of a SEMAC MR measuring sequence, wherein different cycles of the sequence have a different number of read-out read partitions of the slices.

FIG. 15 illustrates an inventive sequence of slices for reading out read partitions within the context of a SEMAC MR measuring sequence, for which corresponding MR data as in FIG. 14 is obtained, wherein all cycles of the sequence have the same predefined number of read-out read partitions.

FIG. 16 is a flowchart of an inventive method for slice-selective MR imaging.

FIG. 17 illustrates schematically a progression of an inventive MR measuring sequence.

FIG. 18 is a flowchart of an inventive method for slice-selective MR imaging.

### DESCRIPTION OF THE PREFERRED EMBODIMENTS

The present invention will be explained in more detail below using preferred embodiments with reference to the drawings. In the figures the same reference numerals designate the same or similar elements. The following description of embodiments with reference to the figures should not be interpreted as limiting. The figures are purely illustrative.

The present invention will be explained in more detail below using preferred embodiments with reference to the drawings. In the figures the same reference numerals designate the same or similar elements. The figures are schematic representations of various embodiments of the invention. Elements illustrated in the figures are not necessarily shown true to scale. Instead the various elements shown in the figures are reproduced in such a way that their function and general purpose can be understood by a person skilled in the art. Links and couplings shown in the figures between functional units and elements can also be implemented as an indirect link or coupling. A link or coupling can be wired or wireless. Functional units can be implemented as hardware, software or a combination of hardware and software.

Techniques of MR imaging will be explained below in conjunction with SEMAC MR measuring sequences in which different slices have a different number of read partitions, i.e. asymmetric SEMAC. Here dead times are avoided by a specific sequence of slices and the measuring time is reduced therewith. The specific sequence can be achieved for example by re-sorting a strictly sequential sequence of slices. At the same time a comparatively high mean or effective repetition time can be achieved between the successive reading out of read partitions of the same slice.

Corresponding read partitions of different slices are conventionally read out in the same cycles of a sequence of slices. The sequence is strictly sequential. According to the invention this pattern is broken since sub-sequences that are different from each other are used. It may then be possible, for instance by re-sorting, for corresponding read partitions of different slices to be read out in different cycles of the sequence. Dead times, which conventionally occur—due to the fact that there are no corresponding read partitions for some slices—can be avoided in such a way.

Such techniques can advantageously be used if there are inhomogeneities of the magnetic field, for example due to orthopedic implants in the examination area. MR imaging on patients with orthopedic implants has developed into an important application over the past years. There is basically the problem in this connection that the different magnetic susceptibilities between metal implants and body tissue disrupt the homogeneity of the magnetic field and significant impairments of the diagnostic image quality of the MR images can occur as a result. In addition to the falsification of the image contrast or signal losses, the geometric distortion of the MR image constitutes a significant problem, wherein the distortion of the excited slice profile in the slice-selective MR imaging again constitutes a dominant cause of the image artifacts produced in the MR image. The techniques for reducing these artifacts according to different reference implementation are typically connected to a significant increase in the RF power deposited in the examination object and in particular also with an increase in the measurement duration.

Techniques will be explained below which, despite the presence of metal implants, improve the applicability of MR imaging in relation to SAR and the measuring time.

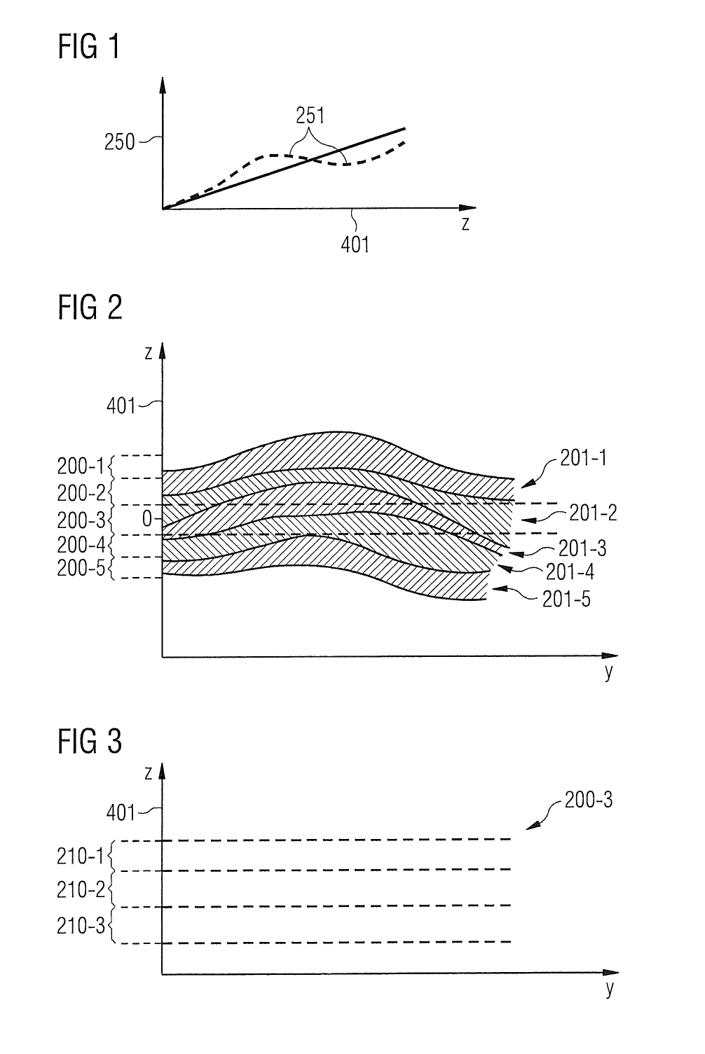

FIG. 1 shows, as an example, an inhomogeneity 251 of the magnetic field 250 in the presence of a slice selection gradient in the slice-selection direction (z direction) 401. The magnetic field can be the locally effective magnetic field (B field). This can differ from the nominally applied basic magnetic field due to susceptibility artifacts and/or demagnetization effects. The ideally present local course of the magnetic field 250 would be linear (shown in FIG. 1 by the solid line). Differences occur with respect to the linear course (shown in FIG. 1 by the broken line) due to the magnetic field inhomogeneity 251. The differences can be so pronounced that there is no longer an unambiguous association between position in the z direction and resonance frequencies (see FIG. 1). Even slight differences may be sufficient, however, to cause significant artifacts, such as distortions, etc. for example in the MR images.

FIG. 2 shows by way of example excitation profiles 201-1, 201-2, 201-3, 201-4, 201-5 which are obtained as a consequence of the slice-selective excitation of the nuclear spin by means of slice selection gradients and time-correlated radiated RF excitation pulse. Due to the magnetic field inhomogeneities 251 these excitation profiles 201-1, 201-2, 201-3, 201-4, 201-5 do not have a planar, level form. To reduce the artifacts it is desirable, however, to obtain MR data from slices 202-1-202-5 which are as planar as possible (shown on the left in FIG. 2). If the slices, for which MR data is acquired, are not planar, distortion artifacts typically occur. Techniques will be illustrated below which allow such artifacts to be reduced.

For this purpose MR data from a plurality of read partitions 210-1-210-3 is read out for each slice, see FIG. 3, where the read partitions 210-1-210-3 for the slice 200-3 are shown. The read partitions are adjacent to each other in the z direction 401 and extend perpendicularly to the z direction 401. The additional encoding in the z direction 401 matches a phase encoding and is often also called SEMAC encoding. The measuring time typically increases linearly with the number of SEMAC steps or read partitions. It may therefore be necessary to strike a balance between adequate reduction of distortions of the imaged examination object on the one hand and increasing the measuring time.

The following example illustrates the lengthening of the measuring time: the measuring time increases as follows in conjunction with T2-weighted turbo spin echo (TSE) protocols with long repetition time TR: 256 phase encoding steps with turbo factor 8 and TR equal to 4 s means a measuring time of 2 min 8 s. If a SEMAC resolution of 16 steps is chosen (16 read partitions per slice), the measuring time increases to over 34 minutes. Such long measuring times can limit applicability for MR imaging processes in practical cases, in particular in clinical protocols.

The number of required SEMAC steps before carrying out the specific measurement is frequently not known and is only determined on the basis of calibration data. The choice of corresponding protocol should cover a worst case scenario in many cases. Typically it may be possible to choose the number of read partitions as a function of a position and location of the corresponding slice in relation to a source of the magnetic field inhomogeneities. In other words, a number of read partitions per slice can be chosen as a function of a distance of the respective slice from a predefined location. The location can mark for example a source of the magnetic field inhomogeneities 251 and/or be determined as a function of a measured off-resonance of the slice. This means that the number of read partitions can vary from slice to slice. In this way it can in particular be possible to reduce the total number of read partitions 210-1, 210-2, 210-3 and to reduce the measuring time in such a way. At the same time, however, dead times can occur during the measurement in the case of conventional SEMAC protocols due to the absence of corresponding read partitions 210-1, 210-2, 210-3 in different slices. Techniques will be illustrated below as to how these dead times can be reduced or avoided.

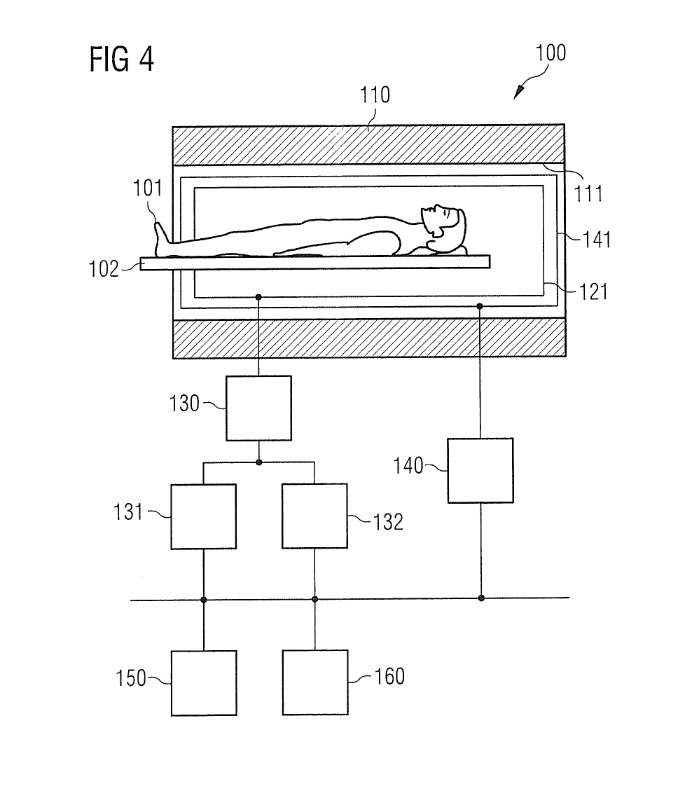

An appropriately configured MR system 100 can be used for this purpose (cf. FIG. 4). The MR system 100 has a magnet 110 which defines a tube 111. The magnet 110 can generate the basic magnetic field parallel to its longitudinal axis. The basic magnetic field can have inhomogeneities, i.e. local differences from a desired value. An examination object, here an examination person 101, can be pushed on an examination couch 102 into the magnet 110. The MR system 100 also has a gradient system 140 for generating gradient fields which are used for MR imaging and for the spatial encoding of acquired raw data. The gradient system 140 typically includes at least three gradient coils 141 that can be controlled separately and are positioned well defined from each other. The gradient coils 141 enable gradient fields to be applied and switched in specific spatial directions (gradient axes). The gradient fields can be used for example for slice selection in the slice-selection direction, for frequency encoding (in the read direction) and for phase encoding. The phase encoding can occur in the slice-selection direction and in a second direction perpendicular thereto. Spatial encoding of the raw data can be achieved thereby. The spatial directions, which are each parallel to slice selection gradient fields, phase encoding gradient fields and read-out gradient fields, do not necessarily have to be coincident with the machine coordinate system.

For example, the examination person 101 can have orthopedic implants. This leads to a local inhomogeneity of the magnetic field. For excitation of the polarization resulting in the basic magnetic field or alignment of the nuclear spins or magnetization in the longitudinal direction an RF coil arrangement 121 is provided which can radiate an amplitude-modulated RF excitation pulse into the examination person 101. The resonance frequency of the nuclear spins varies according to the local magnetic field. The RF excitation pulses must therefore be matched to the local resonance frequency of the nuclear spins. A transverse magnetization of the spins is generated as a result. To generate RF excitation pulses of this kind an RF transmitting unit 131 is connected by an RF switch 130 to the RF coil arrangement 121. The RF transmitting unit 131 can comprise an RF generator and an RF amplitude modulation unit. The RF excitation pulses can tilt the transverse magnetization 1D slice-selectively or 2D, 3D location-selectively or globally from the rest position. Techniques are mentioned in particular here in which a slice-selective excitation occurs.

An RF receiving unit 132 is also coupled by the RF switch 130 to the RF coil arrangement 121. MR signals of the relaxing transversal magnetization can be acquired via the RF receiving unit 132, for example by inductive coupling into the RF coil arrangement 121, as MR data.

In general it is possible to use separate RF coil arrangements 121 for radiation of the RF excitation pulses by means of the RF transmitting unit 131 and for acquiring the MR data by means of the RF receiving unit 132. A volume coil 121 for example can be used for radiating RF pulses and a surface coil (not shown) for acquiring raw data, composed of an array of RF coils. For acquiring the raw data the surface coil can include, for example, 32 individual RF coils and thereby be particularly suitable for partially parallel imaging (ppa imaging, partially parallel acquisition). Appropriate techniques are known to those skilled in the art so further details need not be explained herein.

The MR system 100 also has an operating unit 150 that can include for example a screen, keyboard, mouse, etc. User inputs can be detected by means of the operating unit 150 and output to the user. For example, it may be possible for individual operating modes or parameters of the MR system to be adjusted by the user and/or automatically and/or by remote control by means of the operating unit 150.

The MR system 100 also has an arithmetic unit 160. The arithmetic unit 160 can be configured to carry out diverse arithmetic operations within the context of reworking by way of SEMAC techniques. The artifacts can consequently be reduced. The arithmetic unit 160 can therefore be configured to determine an MR image based on MR data of the read partitions of the respective slice and based on MR data of the read partitions of further slices for each slice.

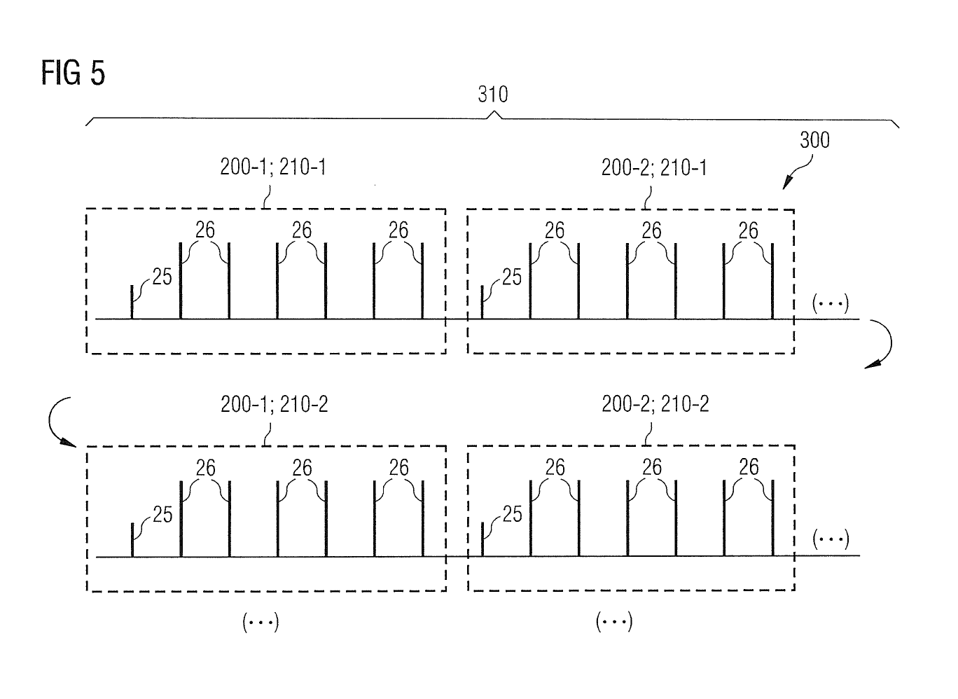

The MR system 100 is also configured to acquire MR data by means of a SEMAC MR measuring sequence, as is illustrated in FIG. 5. FIG. 5 shows a spin echo measuring sequence, as is used in conjunction with SEMAC techniques.

Read partitions 210-1, 210-2 for different slices 200-1, 200-2 are read out within the context of a cyclical sequence 300. In FIG. 5 the parts of the SEMAC MR measuring sequence, which relate to a specific read partition 210-1, 210-2 of a specific slice 200-1, 200-2, are each bordered by means of broken lines and identified as belonging together. It can be seen from FIG. 5 that successively read-out read partitions 210-, 210-2 belong to different slices 200-1, 200-2. This ensures a minimum repetition time between the sequential reading out of read partitions 210-1, 210-2 of the same slice 200-1, 200-2.

Only the reading out of the two read partitions 210-1, 210-2 for the two slices 200-1, 200-2 is shown in the example of FIG. 5. It is of course possible, however, for the sequence 300 to include further slices or further read partitions (not shown in FIG. 5). In particular further read partitions 210-1, 210-2 of other slices can be read out per cycle 310 of the sequence 300.

For each read partition 210-, 210-2 firstly the radiation of RF excitation pulse 25 occurs and then the radiation of a plurality of RF refocusing pulses 26. Spin echoes are formed by the RF refocusing pulses 26, so corresponding MR data can be acquired (not shown in FIG. 5). The RF pulses 25, 26 cause an RF exposure of the examination object which can be quantified by the SAR value.

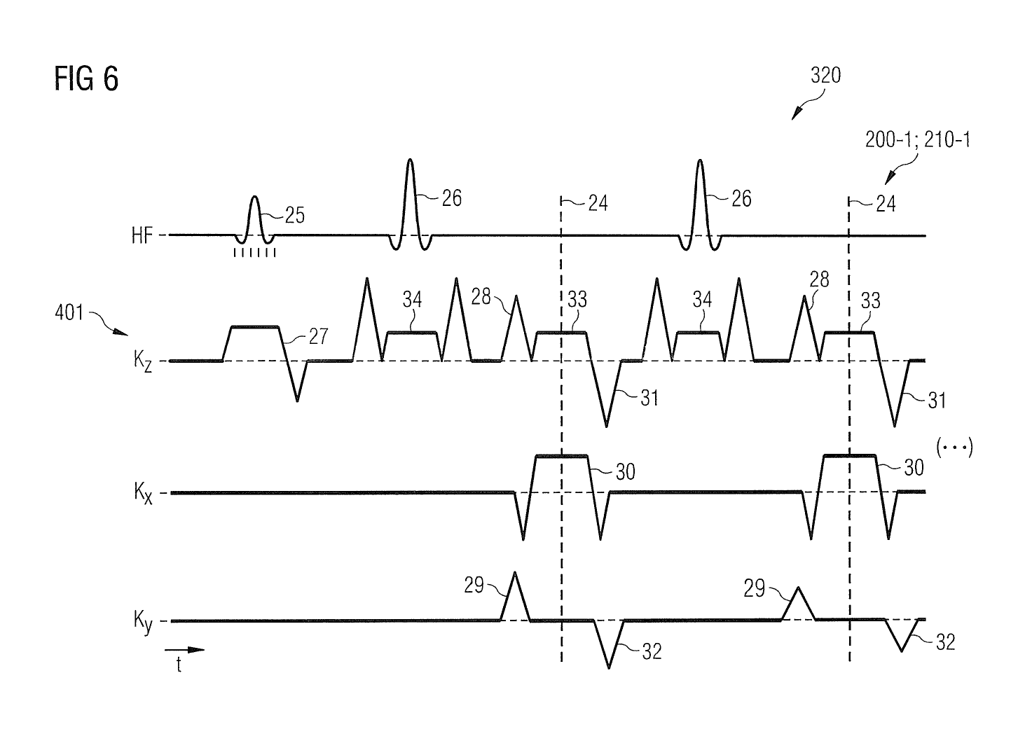

FIG. 6 shows the SEMAC MR measuring sequence for the read partition 210-1 of the slice 200-1 in greater detail. Firstly the radiation of the RF excitation pulse 25 occurs with a specific amplitude-modulated radio-frequency (shown in FIG. 6 by the vertical dashes). A corresponding slice-selection gradient 27 is simultaneously applied, so only nuclear spins of the slice 200-1 are excited. The corresponding excitation profile 201-1-201-5 can be distorted due to the magnetic field inhomogeneity 251. A refocusing pulse 26 is then switched while a further gradient 34 is switched in slice-selection direction kz, so only the nuclear spins in the slice 200-1 are refocused. Phase encoding, which determines the corresponding read partition 210-1, then occurs with a first phase encoding gradient 28. A further phase encoding gradient 29 is applied in the ky direction. A k-space row is then selected by the gradients 28 and 29. MR data with switched read-out gradient 30 is then read out for the selected k-space row in the direction kx. The gradient 33 switched during reading out is used for View-Angle-Tilting (VAT) compensation. A spin echo 24 is formed during the gradient 30. The subsequently switched phase encoding gradients 31, 32 compensate the phase accumulated by the previously switched phase encoding gradients 28, 29. A further spin echo 24 is then formed by the further refocusing pulse 26; the amplitude of the phase encoding gradient 29, 32 is chosen so as to be different in this connection, whereby the next k-space row is selected. The phase encoding gradient fields 28, 31 remain constant, so the same read partition 210-1 is addressed.

This process can then be repeated for an appropriate number of k-space rows by further radiation of refocusing pulses 26.

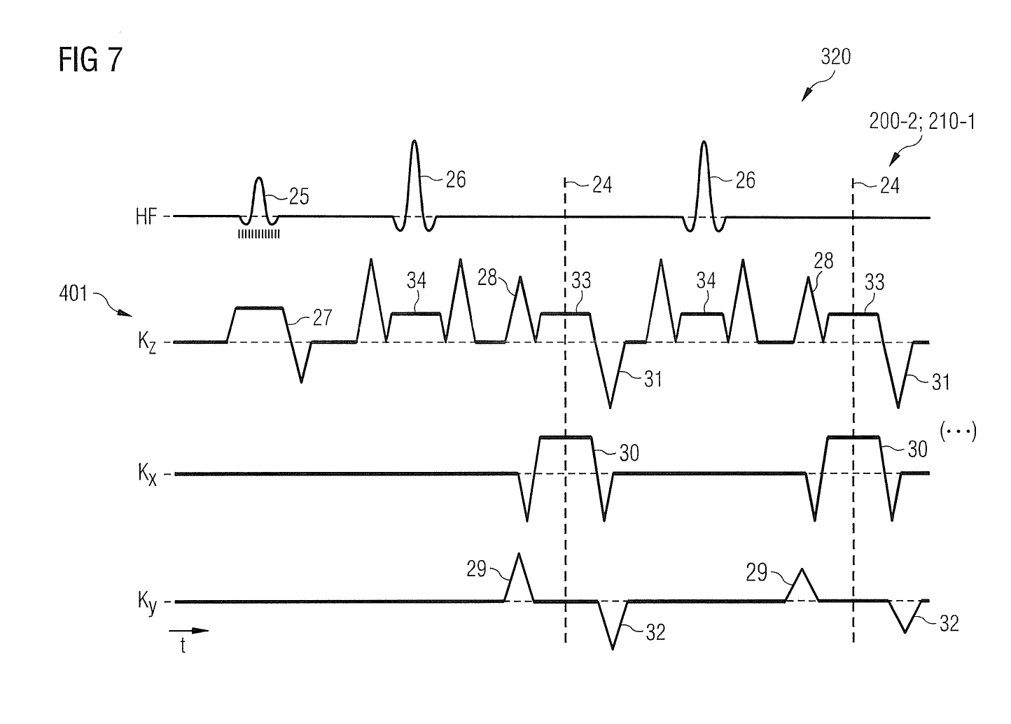

FIG. 7 shows the protocol for the read partition 210-1 (according to FIG. 6) for the further slice 200-2. As may be seen from FIG. 7, only the radio-frequency of the RF excitation pulse 25 or of the refocusing pulses 26 changes (not shown in FIG. 7). The amplitudes of the gradients 28, 31 in particular remain the same, whereby the same read partition 210-1 is addressed.

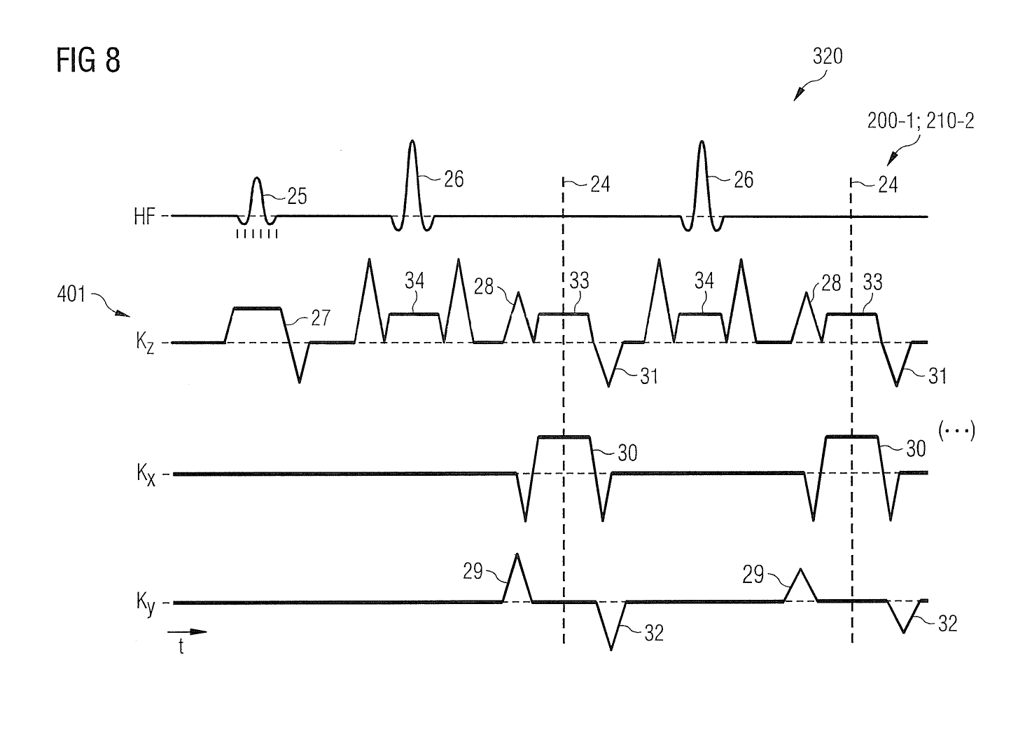

FIG. 8 shows the protocol for a further read partition 210-2 of the first slice 200-1. Compared to FIGS. 6 and 7 the gradients 28, 31 now have different amplitudes for selection of the read partition 210-2.

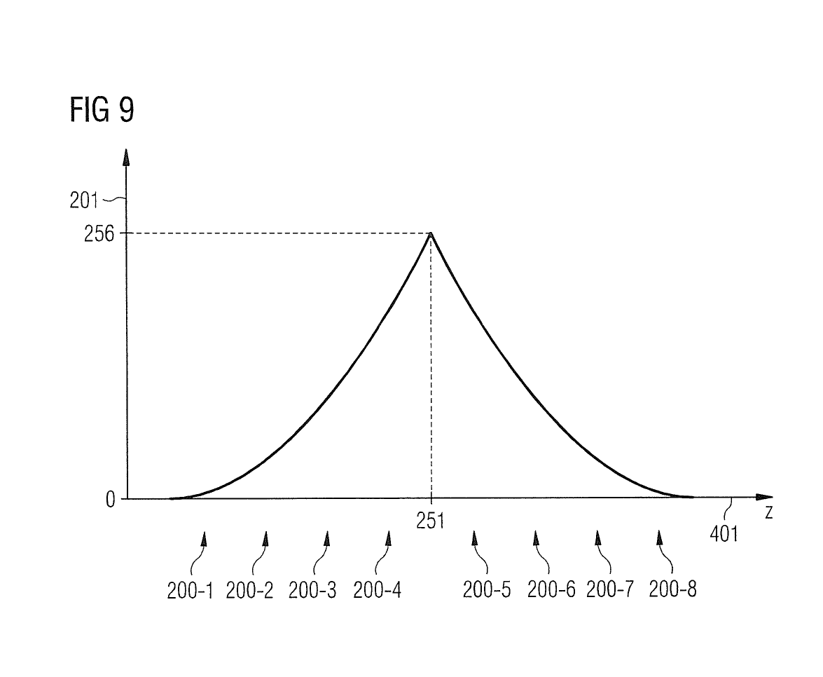

As mentioned in the introduction, different slices 200-1-200-8 have a different number 201 of read partitions 210-1-210-3, see FIG. 9. For example, the number 201 can be chosen as a function of the position in the kz direction 401, for instance more (fewer) slices, the closer (further away) from a source of magnetic field inhomogeneities 251.

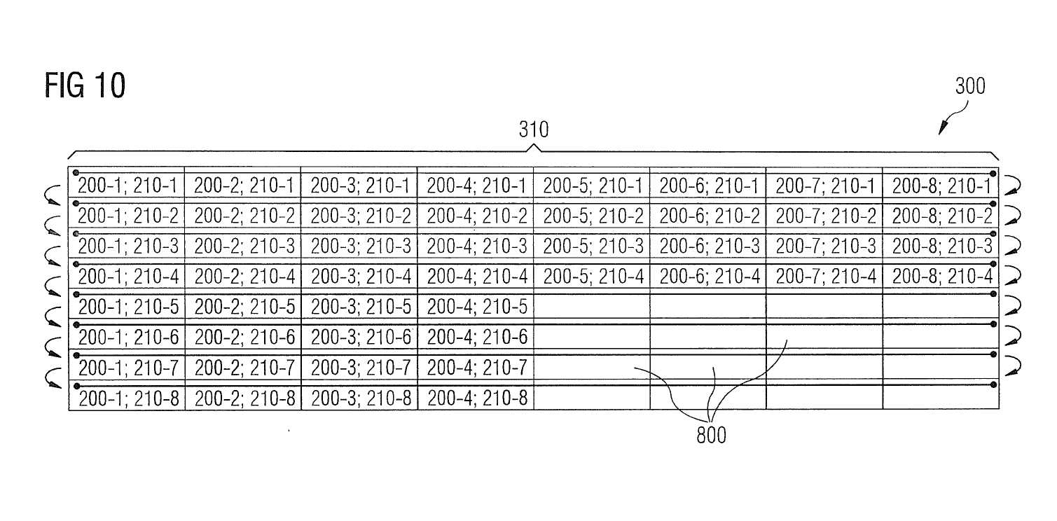

This leads to dead times 800 in conventional measuring protocols which are fixed by a sequence 300 of slices 200-1-200-8 (cf. FIG. 10). In conventional sequences 300 corresponding read partitions 210-1-210-8 are read out for different slices in each cycle 310. Reading out occurs strictly sequentially. In the scenario in FIG. 10 there is for example for the slice 200-5 no read partition 210-5, so there is accordingly a dead time 800 of the measurement there. A fixed repetition time between the successive reading out of read partitions 210-1-210-8 of the same slices 200-1-200-8 can be achieved by the provision of the dead times 800. As may be seen from FIG. 10, the repetition time does not vary the measuring time.

It may also be seen from FIG. 10 that in conventional sequences 300 of slices 200-1-200-8 different cycles 310 of the sequence 300 have a different number of read-out read partitions 210-1-210-8. In the scenario in FIG. 10, therefore, eight read partitions 210-1-210-4 respectively are read out for the different slices 200-1-200-8 in the first four cycles 310, whereas in the last four cycles 310 only four read partitions 210-5-210-8 are read out for the different slices 200-1-200-4 respectively.

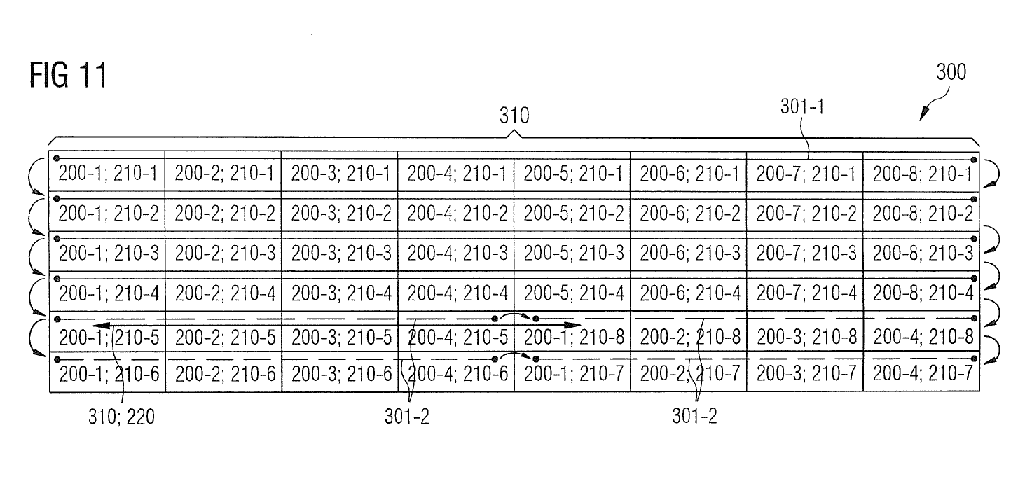

This differs from the corresponding inventive sequence 300 (see FIG. 11), which can be obtained by appropriate re-sorting of the read partitions 210-1-210-8. As may be seen from FIG. 11, the same predefined number—in this case eight—of read partitions 200-1-200-8 is read out for the slices 200-1-200-8 in all cycles 310 of the sequence 300. At the same time the number the cycles 310 is reduced in comparison with the scenario in FIG. 10 (from eight to six cycles 310). The measuring time is consequently reduced. At the same time the SAR present per period is increased, however.

In FIG. 11 the repetition time also varies over the measuring time. This is the case because the read partitions of the different slices 200-1-200-8 are no longer read out strictly sequentially. Sub-sequences 301-1, 301-2 are used. The sequence 300 in the scenario in FIG. 11 is composed of two sub-sequences 301-1, 301-2. In the first sub-sequence 301-1 cyclical iteration occurs through slices 200-1, 200-2, 200-3, 200-4, 200-5, 200-6, 200-7, 200-8. In the second sub-sequence 301-2 cyclical iteration occurs through the slices 200-1, 200-2, 200-3, 200-4.

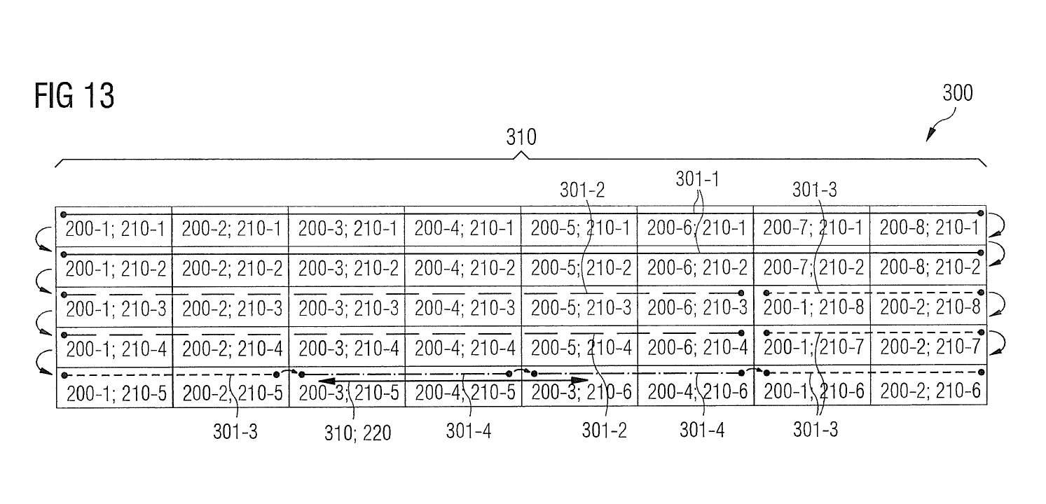

The cycle 310 of the first sub-sequence 301-1 has the same number of read-out read partitions 210-1-210-4 of slices 200-1-200-8 as the cycle 310 of the sequence 300, namely eight in each case. By contrast, the cycle 310 of the second sub-sequence 301-2 has a lower number of read-out read partitions 210-5-210-8 than the cycle 310 of the sequence 300. Per cycle 310 of the second sub-sequence 301-2 four read partitions 210-5-210-8 respectively are read out. The two sub-sequences 301-1, 301-2 have different lengths. A repetition time 220 of the first sub-sequence 301-1 is therefore longer than a repetition time of the second sub-sequence 301-2. The period averaged between the two repetition times 220 of the two sub-sequences 301-1, 301-2 for example could be defined as the effective repetition time. In the scenario in FIG. 11 the two sub-sequences 301-1, 301-2 are read out successively. It is also possible to read out different sub-sequences 301-2-301-4 in an interleaved manner, as shown in FIG. 13.

In the scenario in FIG. 11 the cycle 310 of the sequence 300 is fixed the longest cycle 310 of the sub-sequences 301-1, 301-2, here the cycle 310 of the first sub-sequence 301-2. As may be seen from FIG. 11 there are no longer any dead times 800 because all cycles 310 of the sequence 300 have the same number of read-out read partitions 210-1-210-6 (cf. FIG. 10).

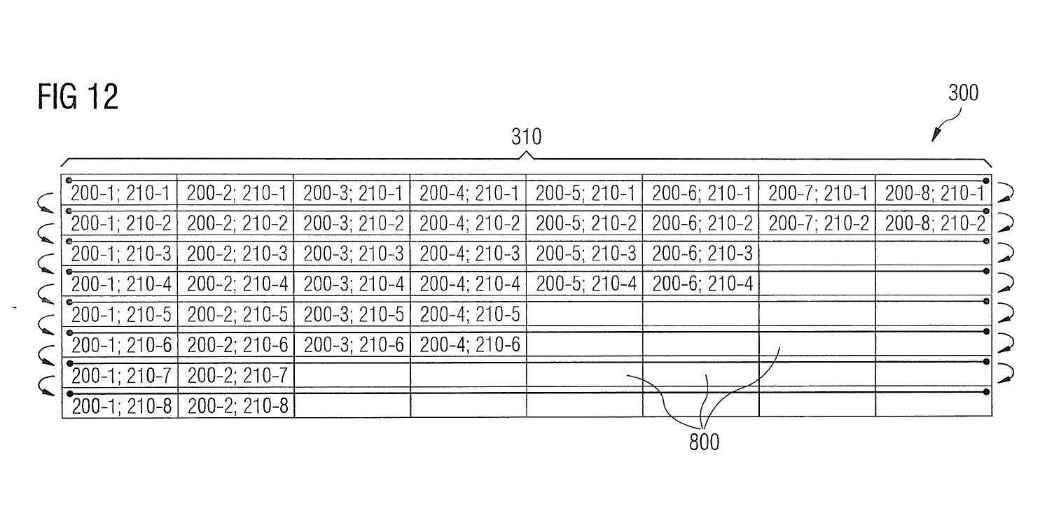

As may be seen from a comparison of FIGS. 12 and 13, the inventive solution provides a reduction in the measuring time by an expedient re-sorting of the read partitions 210-1-210-8 in the protocol sequence. This can occur within the context of a re-sorting process of an original data record, which defines the sequence 300 according to FIG. 12, so the dead times 800 are reduced. In particular re-sorting can occur in such a way that in the re-sorted sequence 300 in FIG. 13 at least two read partitions 210-1-210-8 are read out for the same slice 200-1-200-8 in at least one cycle 310 of the sequence 300. This is achieved by the shortened second sub-sequence 201-2. Consequently this means that in all cycles 310 of the re-sorted sequence 300 in FIG. 13 the same predefined number of read partitions 210-1-210-8 is read out for the slices 200-1-200-8, in the example of FIG. 11 eight read partitions 210-1-210-8 in each case.

In general a wide variety of techniques can be used for re-sorting. One technique which could be used within the context of re-sorting will be described purely as examples below. The number of read partitions 210-1-210-8 of the respective slice 200-1-200-8 is given by the function ƒ(#s). This means that #s=1 to #s=max can vary.

The total number of read partitions 210-1-210-8 results as: # SEMAC=Sum_{(#s=1 . . . max)}(ƒ(#s))

The total number of repetitions or cycles 310 is given by: # R=RoundUp(# SEMAC/# s=max), wherein RoundUp designates rounding up to the next whole number.

#R can also be chosen to be greater than Roundup(#SEMAC/# s=max) if the repetition time is to be shortened or the SAR is to be reduced.

The slices 200-1-200-8 are then sorted and combined according to number of the read partitions 210-1-210-8. This can occur for example as follows, wherein it is assumed that the data record is ordered in the manner of a matrix into rows and columns as shown in FIG. 10.

Here a row designates a cycle 310 of the sequence 300. A column corresponds to the same positions within a cycle 310 of the sequence 300 or optionally corresponding instants within a repetition time 220.
Choose the slice 200-1-200-8 with maximum ƒ(#s) and
choose the slice 200-1-200-8 with minimum ƒ(#s) and
write this in a column (cf. FIGS. 10 and 11).
It is optionally possible for the sequence of the slice 200-1-200-8 to be reversed with fewer read partitions.

It can be desirable for the number of entries in each new column to be a whole multiple of #R; other combinations are also conceivable: the read partitions 210-1-210-8 of more than two slices 200-1-200-8 are written in a column one below the other or split among a plurality of columns.

A division into sub-columns then occurs. The division factor is defined as # U=# SEMAC/# R/# s, wherein #S designates the number of new columns compared to the original data record. Each new column is divided into #U sub-columns. The sub-columns are divided among the number #SEMAC/# again. It is in turn possible to invert the sequence of individual columns.

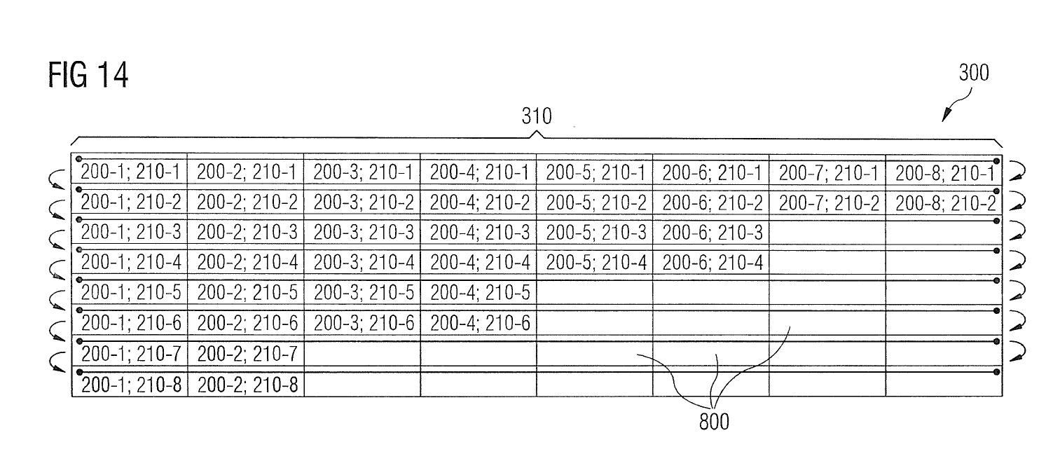

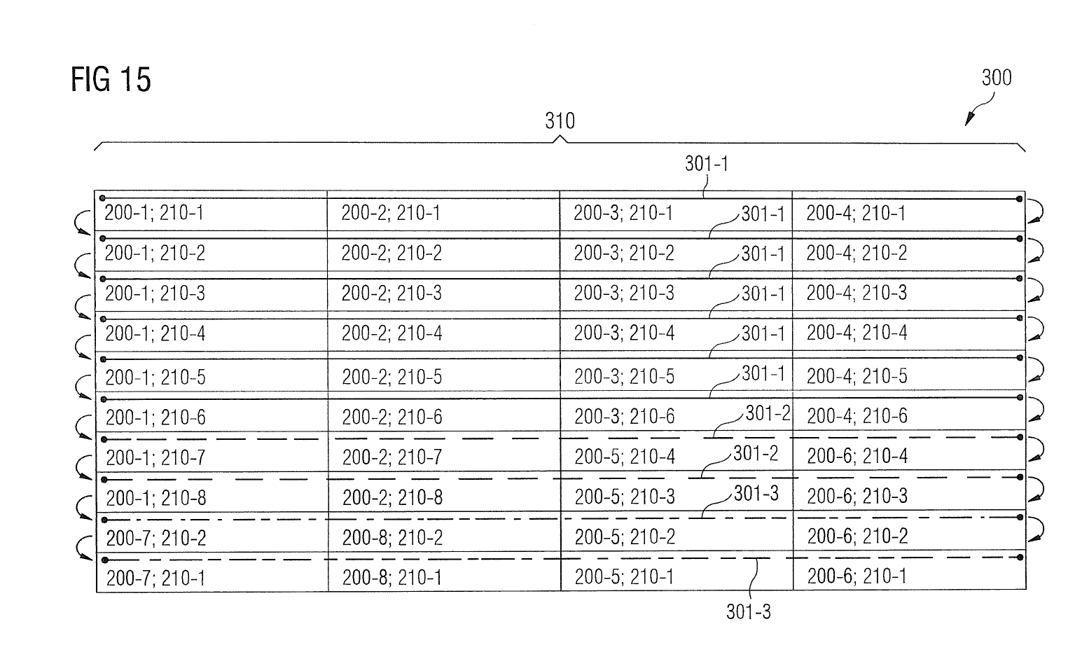

Of course the above-described technique is just one of various techniques for obtaining an inventive sequence 300 according to FIG. 11. Other re-sorting techniques are also conceivable. Further application examples for above-described techniques for re-sorting are shown in FIGS. 12 and 13 as well as 14 and 15 respectively. It can be seen from each of these figures that the unsorted sequence 300 in FIGS. 12 and 14 has a different number of read partitions 210-1-210-8 per cycle 310 but a constant repetition time. Dead times 800 occur. The inventive sequences 300 in FIGS. 13 and 15 are each obtained by re-sorting. In the scenario in FIG. 15 a total number of cycles 310 of the sequence 300 is greater than a maximum number of read partitions 210-1-210-8 per slice 200-1-200-8. Ten cycles 310 are run through while a maximum number of read partitions 210-1-210-8 assumes the value 8. The repetition time 220 can be reduced in this way. In the scenario in FIG. 15 the number of read partitions 210-1-210-8 per cycle 310 of the sequence 200 is less than the total number of slices 200-1-200-8. In the scenario in FIG. 15 four read partitions 210-1-210-8 are iterated per cycle 310, whereas the total number of slices 200-1-200-8 is eight. In the scenario in FIG. 15 it can also be seen that the cycles 310 of the sub-sequences 301-1-301-3 each have the same predefined number of read-out read partitions 210-1-210-8 as the cycle 310 of the sequence 300, namely four in each case. This means that the cycles 310 of the sub-sequences 301-1-301-3 all have the same length (in contrast for example to the scenario in FIGS. 11 and 13).

In the scenario in FIG. 15 the first sub-sequence 301-1 has the amount of slices 200-1, 200-2, 200-3, 200-4. By contrast, the second sub-sequence 301-2 has the amount of slices 200-1, 200-2, 200-5, 200-6. This means that the first and second amounts partly overlap. In contrast to this the third and fourth sub-sequences 201-3, 201-4 in the scenario in FIG. 13 have disjunct amounts of slices 200-1, 200-2, 200-3, 200-4.

To reduce the SAR it would be possible in each of said scenarios to provide a specific predefined dead time following each cycle 310. The SAR per time interval could be reduced thereby. Nevertheless, in such a case—in contrast to known solutions—all cycles 310 have the same predefined number of read partitions 210-1-210-8.

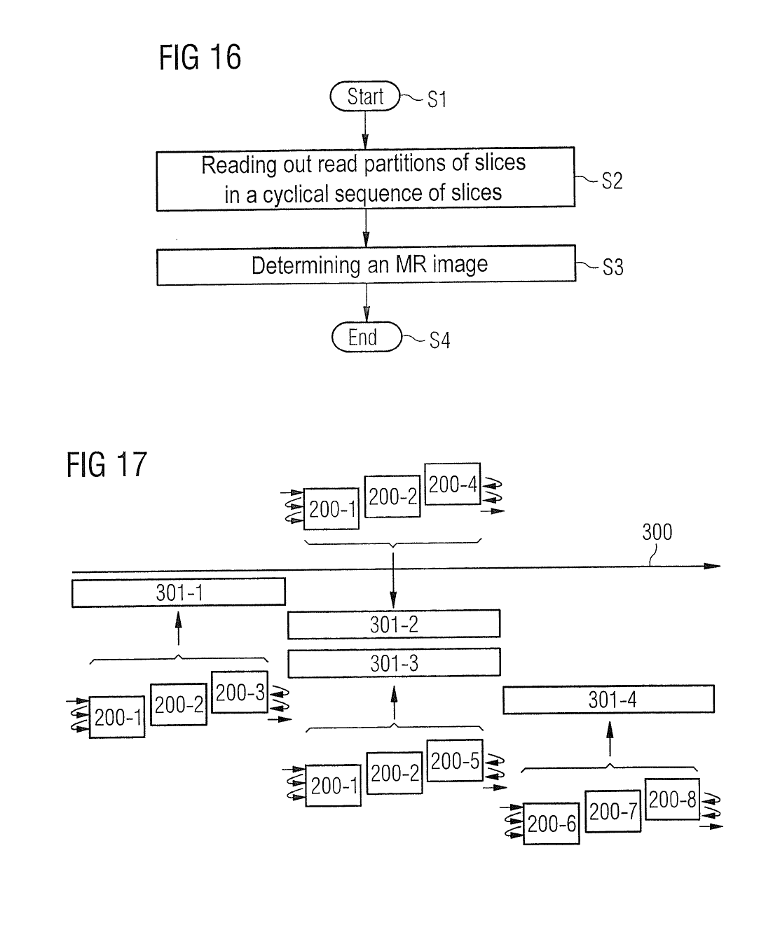

FIG. 16 shows a flowchart of an inventive method for slice-selective MR imaging a plurality of slices 200-1-200-8. The method begins in step S1. First the read partitions 210-1-210-8 of the slices 200-1-200-8 are read out in a cyclical sequence 300 in step S2. From the MR data acquired in such a way an MR image is determined by means of arithmetic unit 160 in step S3. The method ends in step S4. FIG. 17 shows a course over time 300 for different sub-sequences 301-1-301-4 of the sequence 300 from step S2. Different slices 200-1-200-8 are associated with the different sub-sequences in each case, for which slices read partitions 210-1-210-8 are read out respectively. While the sub-sequences 301-1 and 301-4 are read out sequentially the sub-sequences 301-2, 301-3 are read out in an interleaved manner. Dead times 800 can be avoided by means of the use of the sub-sequences 301-1-301-4.

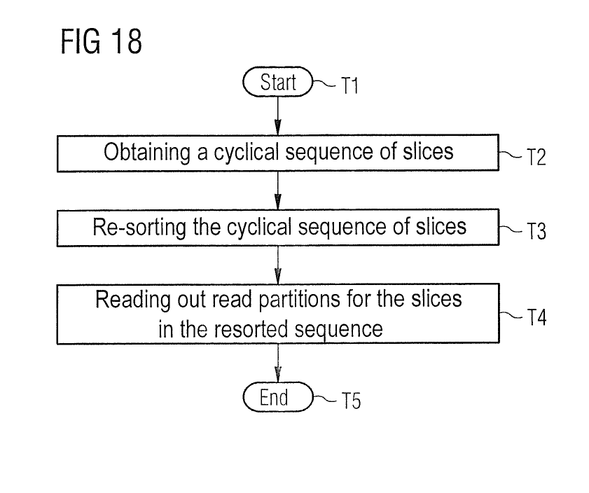

FIG. 18 shows a flowchart of a further inventive method for slice-selective MR imaging a plurality of slices 200-1-200-8 of an examination object. The method begins in step T1. Firstly a data record is obtained in step T2 which defines the cyclical sequence 300 of slices 200-1-200-8 in a strictly sequentially sorted state (cf. FIG. 10, 12, 14). These sequences 300 have dead times 800 since different cycles 310 have a different number of read-out read partitions 210-1-210-8, wherein a fixed repetition time is implemented at the same time. In step T3 this cyclical sequence 300 is then re-sorted. The re-sorting occurs in such a way that the dead times 800 are eliminated. Sub-sequences 301-1-301-4 are formed to which different slices 200-1-200-8 respectively are allocated. The corresponding read partitions 210-1-210-8 are then read out in step T4. The method ends in step T5.

The features of the embodiments described above and aspects of the invention can be combined with each other. In particular the features can be used not just in the described combinations but also in other combinations or alone, without departing from the field of the invention.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for slice-selective magnetic resonance (MR) imaging of a plurality of slices of an examination subject, comprising:
from a control computer, operating an MR scanner, while an examination subject is situated in the MR scanner, to slice-selectively acquire MR data from each of a plurality of slices of the examination subject, wherein slices in said plurality of slices are respective adjacent to each other along a first direction and extend perpendicularly to said first direction;
from said control computer, operating said MR scanner to acquire said MR data from said plurality of slices in a plurality of read partitions in each slice, the read partitions of each slice being adjacent to each other along said first direction, and at least two slices in said plurality of slices having a different number of said read partitions;
from said control computer, operating said MR scanner to read out MR data in said read partitions in a cyclical sequence of the slices in said plurality of slices with successive read-out read partitions respective being in different slices, and maintaining a minimum repetition time between sequential readout of respective read partitions of a same slice and wherein a same predetermined number of read partitions is read out in each cycle of said cyclical sequence, and with said cyclical sequence comprising at least two sub-sequences that differ from each other with respect to one of said slices in said plurality of slices; and
providing said MR data to an image reconstruction computer and, in said image reconstruction computer, reconstructing an MR image for each slice from the MR data of the read partitions of that respective slice and MR data of read partitions of other slices in said plurality of slices.

2. A method as claimed in claim 1 comprising, in said control computer, selecting said predetermined number of read partitions in each cycle in said cyclical sequence to be lower than a total number of slices in said plurality of slices.

3. A method as claimed in claim 1 comprising, from said control computer, operating said MR scanner to execute a total number of cycles in said cyclical sequence that is greater than a maximum number of said read partitions in each slice in said plurality of slices.

4. A method as claimed in claim 1 comprising operating said MR scanner to execute said at least two sub-sequences successively or in an interleaved manner.

5. A method as claimed in claim 1 comprising, from said control computer, operating said MR scanner with a first of said sub-sequences comprising a same number of read-out read partitions as cycles in said cyclical sequence and wherein a second of said sub-sequences comprises a lower number of read-out read partitions than cycles of said cyclical sequence.

6. A method as claimed in claim 5 comprising, from said control computer, operating said MR scanner with a repetition time of said first of said sub-sequences being longer than a repetition time of a second of said sub-sequences.

7. A method as claimed in claim 1 comprising, from said control computer, operating said MR scanner with cycles of said at least two sub-sequences having a same predetermined number of read-out read partitions as cycles of said cyclical sequence.

8. A method as claimed in claim 1 comprising, from said control computer, operating said MR scanner with a first group of slices, among said plurality of slices, having read partitions that are read out in a first of said sub-sequences being different from a second group of slices, in said plurality of slices having read partitions that are read out in a second of said sub-sequences.

9. A method as claimed in claim 8 wherein said first and second groups are disjunct from each other, or partially overlap.

10. A method as claimed in claim 1 comprising, from said control computer, operating said MR scanner with a total number of cycles in said cyclical sequence equal to a total number of said read partitions of all slices in said plurality of slices, divided by a maximum number of read partitions per slice.

11. A method as claimed in claim 1 comprising, from said control computer, operating said MR scanner with each cycle of said cyclical sequence comprising a predetermined dead time having a predetermined duration, without application of any gradients or radio-frequency pulses.

12. A method as claimed in claim 1 comprising, from said control computer, operating said MR scanner to select a number of read partitions per slice dependent on a distance of a respective slice from a predetermined location, said location being selected from the group consisting of a source of magnetic field inhomogeneities of a basic magnetic field generated in said MR scanner, and a location determined dependent on a measured off-resonance of the respective slice.

13. A method as claimed in claim 1 comprising, from said control computer, operating said MR scanner to read out said MR data from each read partition by:
slice-selective excitation of nuclear spins in the respective slice by applying at least one slice selection gradient in said first direction correlated in time with radiation of at least one excitation pulse;
slice-selective refocusing of the excited nuclear spins in the respective slice by sequential application of a plurality of further slice selection gradients in said first direction correlated in time with radiation of a plurality of refocusing pulses; and
for each further slice selection gradient with a correlated refocusing pulse, applying at least one phase encoding gradient in said first direction that defines a read partition, and applying at least one phase encoding gradient in a second direction for acquiring the MR data, wherein said first direction and said second direction are perpendicular to each other.

14. A method as claimed in claim 1 comprising, from said control computer, operating said MR scanner to acquire said MR data in an interleaved SEMAC MR data acquisition sequence.

15. A magnetic resonance (MR) apparatus comprising:
an MR scanner;
a control computer configured to operate said MR scanner, while an examination subject is situated in the MR scanner, to slice-selectively acquire MR data from each of a plurality of slices of the examination subject, wherein slices in said plurality of slices are respective adjacent to each other along a first direction and extend perpendicularly to said first direction;
said control computer being configured to operate said MR scanner to acquire said MR data from said plurality of slices in a plurality of read partitions in each slice, the read partitions of each slice being adjacent to each other along said first direction, and at least two slices in said plurality of slices having a different number of said read partitions;
said control computer being configured to operate said MR scanner to read out MR data in said read partitions in a cyclical sequence of the slices in said plurality of slices with successive read-out read partitions respective being in different slices, and to maintain a minimum repetition time between sequential readout of respective read partitions of a same slice, and to read out a same predetermined number of read partitions in each cycle of said cyclical sequence, and with said cyclical sequence comprising at least two sub-sequences that differ from each other with respect to one of said slices in said plurality of slices; and
a reconstruction computer provided with said MR data, said image reconstruction computer being configured to reconstruct an MR image for each slice from the MR data of the read partitions of that respective slice and MR data of read partitions of other slices in said plurality of slices.

16. A method for slice-selective magnetic resonance (MR) imaging of a plurality of slices of an examination subject, comprising:
from a control computer, operating an MR scanner, while an examination subject is situated in the MR scanner, to slice-selectively acquire MR data from each of a plurality of slices of the examination subject, wherein slices in said plurality of slices are respective adjacent to each other along a first direction and extend perpendicularly to said first direction;
from said control computer, operating said MR scanner to acquire said MR data from said plurality of slices in a plurality of read partitions in each slice, the read partitions of each slice being adjacent to each other along said first direction, and at least two slices in said plurality of slices having a different number of said read partitions;
from said control computer, prescribing a cyclical sequence for acquiring said MR data from respective slices in said plurality of slices, wherein MR data are acquired from at most one read partition per slice in each cycle, with a different number of read partitions being read out in at least two cycles of said cyclical sequence, with dead times occurring during within said cyclical sequence;
in said control computer, re-sorting the prescribed cyclical sequence to reduce said dead times, thereby obtaining a re-sorted sequence; and
from said control computer, operating said MR scanner to read out said MR data from said read partitions for said different slices according to said re-sorted sequence.

17. A method as claimed in claim 16 comprising, in said control computer, re-sorting said prescribed cyclical sequence to cause at least two read partitions, in said re-sorted sequence, for a same slice to be read out in at least one cycle.

18. A method as claimed in claim 16 comprising, in said control computer, re-sorting said prescribed cyclical sequence to cause a same predetermined number of read partitions for respective slices to be read out in all cycles of said re-sorted sequence.

19. A method as claimed in claim 16 comprising, in said control computer, re-sorting said prescribed cyclical sequence to cause a number of read-out read partitions per cycle in said re-sorted sequence to be lower than a number of read-out read partitions per cycle in said prescribed cyclical sequence.

20. A method as claimed in claim 16 comprising, in said control computer, re-sorting said prescribed sequence to cause a total number of cycles in said re-sorted sequence to be larger than a total number of cycles in said prescribed cyclical sequence.
